(19) United States
(12) Patent Application Publication
(10) Pub. No.: US 2006/0286804 A1
(43) Pub. Date: Dec. 21, 2006

(54) Method for forming patterned material layer

(76) Inventors: Chuan-Yi Wu, Taipei City (TW); Chin-Long Chen, Taipei City (TW); Yung-Chia Kuan, Taipei City (TW)

Correspondence Address: J C PATENTS, INC., 4 VENTURE, SUITE 250, IRVINE, CA, 92618, US

(21) Appl. No.: 11/154,412

(22) Filed: Jun. 15, 2005

(51) Int. Cl. H01L 21/302

(52) U.S. Cl. 438/689

(57) ABSTRACT

A method for forming a patterned material layer comprises the following steps. First, a material layer is formed on a substrate, and then a patterned positive photoresist layer is formed on the material layer. Next, the material layer is etched by using the patterned positive photoresist layer as a mask. Afterwards, a developing process is performed to remove the patterned positive photoresist layer. As mentioned above, the cost by using the method of the present invention can be reduced.

### BACKGROUND OF THE INVENTION

1. Field of the Invention

The present invention relates to a manufacturing process in semiconductor fields. More particularly, the present invention relates to a method for forming patterned material layer.

2. Description of Related Art

With the growing of demands in display apparatuses, more and more resources are invested in development of display apparatuses. The cathode ray tube (CRT) has its excellent display quality and technical maturity, so the display market is monopolized by the CRT display for a long time. Compared with other display categories, the CRT display not only has much more power-consumption and radiation adverse to environmental protection, but also has larger product volume, so the CRT display cannot meet with the demands for light weight, thin thickness and low power-consumption in display market. On the contrary, the thin film transistor liquid crystal display (TFT-LCD) has become the mainstream in display markets due to its higher display quality, lower thickness, low power consumption and lower radiation.

As for the thin film transistor liquid crystal display module (TFT-LCD module), it comprises a liquid crystal display panel (LCD panel) and a back light module (B/L module). The LCD panel comprises a thin film transistor array substrate (TFT array substrate), a color filter substrate (C/F substrate) and a liquid crystal layer disposed therebetween. The back light module provides the plane light source for the LCD panel to display.

Whether the manufacturing process for TFT array substrate or the manufacturing process for color filter substrate, a great deal of photolithography processes and etching processes are utilized during these manufacturing processes, wherein the photolithography processes include the exposure processes and the develop processes. As for the method for patterning a metal layer, it comprises the following steps. First, forming a metal layer and a photoresist layer on a substrate sequentially. Next, performing an exposure process and a develop process on the photoresist layer to form a patterned photoresist layer. And then, the metal layer is etched by utilizing the patterned photoresist layer as a mask to form a patterned metal layer. Afterwards, the patterned photoresist layer is removed by using the photoresist-striping liquid to expose the patterned metal layer.

It should be noted that, the components of the photoresist-striping liquid include a monoethanolamine (MEA) and a dimethylsulfoxide (DMSO). The cost of dealing with the waste water containing the DMSO is so high because the DMSO is an organic solvent to influence environment strongly. In addition, the container for storing the DMSO must have the heat-insulating function because the fusion point of the DMSO is 18.5 degree Celsius. Noticeably, an extra cleansing process is required to be performed to decrease the pollution of the photoresist-striping liquid towards the patterned metal layer after the patterned photoresist layer is striped by using the photoresist-striping liquid containing the DMSO. In other words, these manufacturing processes by utilizing the photoresist-striping liquid containing the DMSO will not only produce a great deal of waste water, but also damage or pollute the patterned metal layer.

### SUMMARY OF THE INVENTION

Accordingly, the present invention is directed to a method for forming a patterned material layer capable of decreasing the toxicity of the waste water during its manufacturing process.

In order to achieve the object described above or other objects, the present invention is directed to a method for forming a patterned material layer. The method comprises the following steps. First, forming a material layer on a substrate and then forming a patterned positive photoresist layer on the material layer. Next, etching the material layer by using the patterned positive photoresist layer as a mask. Afterwards, performing a first exposure process on the patterned positive photoresist layer. Finally, performing a first develop process to remove the patterned positive photoresist layer.

According to an embodiment of the present invention, during the first exposure process, a light source utilized is an ultraviolet ray whose wavelength scope can be between 200 nm and 400 nm.

According to an embodiment of the present invention, during the first develop process, a develop liquid utilized is an organic alkaline solvent or an inorganic alkaline solvent, wherein the organic alkaline solvent can be tetramethyl ammonium hydroxide (TMAH) and the inorganic alkaline solvent can be sodium hydroxide (NaOH) or potassium hydroxide (KOH).

According to an embodiment of the present invention, wherein the step of forming the patterned positive photoresist layer comprises the following steps. First, forming a positive photoresist layer on the material layer. Next, performing a second exposure process on the positive photoresist layer. And then, the patterned positive photoresist layer is formed by performing a second develop process. In addition, the light sources utilized during the second exposure process and the first exposure process are the same. The develop liquids utilized during the second exposure process and the first exposure process are the same.

According to an embodiment of the present invention, the material layer can be an organic material layer or an inorganic material layer. In addition, the material layer can also be a dielectric layer, a semiconductor layer or a conductor layer, wherein the conductor layer comprises a metal layer or a transparent conductor layer. The material of the transparent conductor layer comprises an indium-tin oxide (ITO), an indium-zinc oxide or a zinc-aluminum oxide.

According to an embodiment of the present invention, wherein a material of the patterned positive photoresist layer comprises G-line photoresist, I-line photoresist, H-line photoresist or deep ultra-violet (DUV) photoresist.

To sum up, the waste water produced during the present invention, the method for forming a patterned material layer, will not contain the dimethylsulfoxide (DMSO) liquid, because the exposure process is performed on the patterned photoresist layer once again and the develop liquid is utilized to remove the patterned material layer. In other words, compared to the conventional manufacturing process which utilizes the dimethylsulfoxide (DMSO) liquid, the amount of waste water produced by the present invention and the toxicity thereof will be decreased significantly.

### BRIEF DESCRIPTION OF THE DRAWINGS

FIGS. 1A to 1D show the method for forming a patterned material layer according to one embodiment of the present invention.

### DESCRIPTION OF THE EMBODIMENTS

Various specific embodiments of the present invention are disclosed below, illustrating examples of various possible implementations of the concepts of the present invention. The following description is made for the purpose of illustrating the general principles of the invention and should not be taken in a limiting sense. The scope of the invention is best determined by reference to the appended claims.

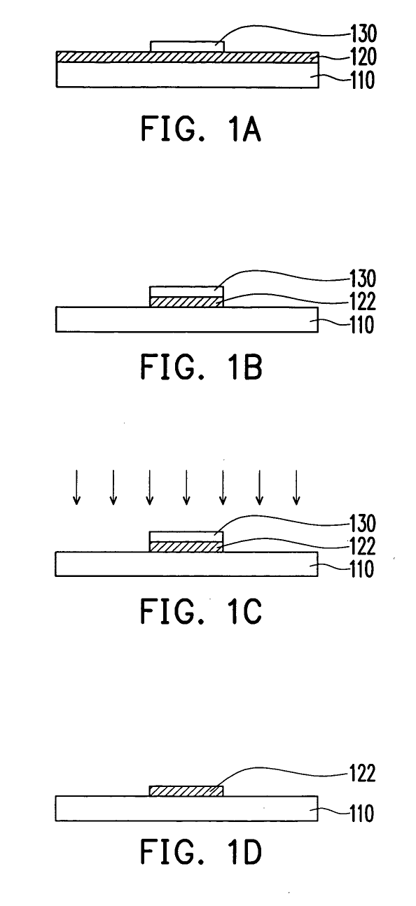

FIGS. 1A to 1D show the method for forming a patterned material layer according to one embodiment of the present invention. Referring to FIG. 1A, the method for forming a patterned material layer of the present invention comprises the following steps. First, a substrate 110 is provided, wherein the material thereof can be quartz, glass, platstic, silicon or other materials. And then, a material layer 120 is formed on the substrate 110, wherein the material layer 120 can be a dielectric layer, a semiconductor layer, a conductor layer, an organic material layer or an inorganic material layer, and wherein the conductor layer can be a metal layer or a transparent conductor layer. For example, the material of the transparent conductor layer is an indium-tin oxide (ITO), an indium-zinc oxide, a zinc-aluminum oxide or other transparent conductor materials.

In other words, the materials of the material layer 120 is not limited by the present invention, so a method for forming the material layer 120 are different according to different materials of the material layer 120. For instance, the method for forming the material layer 120 can be an evaporation process, a sputtering process, a chemical vapor deposition process (CVD), a physical vapor deposition process (PVD), or other film-formed processes.

And then, a patterned positive photoresist layer 130 is formed on the material layer 120, wherein the material of the patterned positive photoresist layer 130 can be G-line photoresist (436 nm), I-line photoresist (365 nm), H-line photoresist (405 nm), DUV photoresist or other positive photoresists according to different wavelengths of light for exposure, and wherein the G-line photoresist and the I-line photoresist can be formed by disposing Novolac into diazonaphthoquinone (DNQ), for example. Specifically, the method for forming the patterned positive photoresist layer 130 comprises the following steps. First, a positive photoresist layer (not shown) is formed on the material layer 120, wherein the method for forming the positive photoresist layer can be a spin coating process or other appropriate manufacturing processes. Next, an exposure process and a develop process are performed sequentially on the positive photoresist layer to form the patterned positive photoresist layer 130. Generally, a hard bake process is performed on the patterned positive photoresist layer 130 after performing the develop process.

In addition, the light source utilized during the develop process can be ultraviolet rays or other appropriate light source, wherein the wavelength scope of the ultraviolet rays can be between 200 nm and 400 nm. Furthermore, the develop liquid utilized during the develop process is an organic alkaline solvent or an inorganic alkaline solvent, wherein the organic alkaline solvent can be tetramethyl ammonium hydroxide (TMAH) or other appropriate liquids. And the inorganic alkaline solvent can be sodium hydroxide (NaOH), potassium hydroxide (KOH) or other appropriate liquids.

Referring to FIG. 1B, a patterned material layer 122 is formed by the patterned positive photoresist layer 130 as a mask. If the materials of the material layer 120 are different, the methods for etching the material layer 120 will be different. For example, the method for etching the material layer 120 can be a wet etching processe or a dry etching process, wherein the dry etching process is used for etching silicon, silicon dioxide, silicon nitride (Si₃N₄), metal or conductor materials. And the wet etching process is used for etching the dielectric, metal or transparent conductor materials.

Referring to FIG. 1C, the patterned positive photoresist layer 130 is fully exposed to light and then the molecular structure of the patterned positive photoresist layer 130 has been changed, so the patterned positive photoresist layer 130 being exposed to light once again will be dissolved in the develop liquids. In addition, the light source utilized during the exposure process is an ultraviolet ray, X-ray or other appropriate light sources, wherein the wavelength scope of the utilized ultraviolet ray can be between 200 nm and 400 nm. In other words, the utilized light source herein and the utilized light source for forming the patterned positive photoresist layer 130 can be the same or different.

Referring to FIG. 1D, a develop process is performed to remove the patterned positive photoresist layer 130 which has been exposed to light once again. For example, during the aforementioned develop process, a develop liquid utilized can be an organic alkaline solvent or an inorganic alkaline solvent, wherein the organic alkaline solvent can be tetramethyl ammonium hydroxide (TMAH) or other appropriate liquids. And the inorganic alkaline solvent can be sodium hydroxide (NaOH), potassium hydroxide (KOH) or other appropriate liquids. In other words, the utilized develop liquid herein and the utilized develop liquid for forming the patterned positive photoresist layer 130 can be the same or different. Noticeably, the utilized develop liquid for forming the patterned positive photoresist layer 130 can be recycled to remove the patterned positive photoresist layer 130, and then the production cost of forming a patterned material layer will be decreased significantly.

In conclusion, the present invention, the method for forming a patterned material layer, at least has the following advantages.

First, compared to the conventional method of removing the patterned photoresist layer by utilizing the photoresist-striping liquid, an exposure process is performed by the present invention once again on the patterned photoresist layer and then the patterned photoresist layer is removed by utilizing the develop liquid. Therefore, the waste water produced by utilizing the present invention will not contain the photoresist-striping liquid (i.e. dimethylsulfoxide, DMSO). That is, in the present invention, the toxicity of the waste water and the cost of dealing therewith will be decreased significantly.

Second, compared to the conventional method, the time-consumption and the water-consumption for removing the patterned photoresist layer of the present invention will be decreased significantly.

Third, because the present invention, the method for forming a patterned material layer, is compatible with the existing manufacturing processes, other additional types of the manufacturing apparatuses will not be further required.

Fourth, compared to the conventional manufacturing process which utilizes the photoresist-striping liquid (such as dimethylsulfoxide, DMSO) to dissolve organic materials (i.e. substrate, conductor, semi-conductor and dielectric layers), the aforementioned problems will be reduced without using the photoresist-striping liquid in the present invention.

The above description provides a full and complete description of the embodiments of the present invention. Various modifications, alternate construction, and equivalent may be made by those skilled in the art without changing the scope or spirit of the invention. Accordingly, the above description and illustrations should not be construed as limiting the scope of the invention which is defined by the following claims.

What is claimed is:

1. A method for forming a patterned material layer, comprising:
forming a material layer on a substrate;
forming a patterned positive photoresist layer on the material layer;
etching the material layer by using the patterned positive photoresist layer as a mask;
performing a first exposure process on the patterned positive photoresist layer; and
performing a first develop process to remove the patterned positive photoresist layer.

2. The method for forming a patterned material layer of claim 1, wherein a light source utilized during the first exposure process is an ultraviolet ray.

3. The method for forming a patterned material layer of claim 2, wherein a wavelength scope of the ultraviolet ray is between 200 nm and 400 nm.

4. The method for forming a patterned material layer of claim 1, wherein a develop liquid utilized during the first develop process is an organic alkaline solvent or an inorganic alkaline solvent.

5. The method for forming a patterned material layer of claim 4, wherein the organic alkaline solvent comprises tetramethyl ammonium hydroxide (TMAH).

6. The method for forming a patterned material layer of claim 4, wherein the inorganic alkaline solvent comprises sodium hydroxide (NaOH) or potassium hydroxide (KOH).

7. The method for forming a patterned material layer of claim 1, wherein the step of forming the patterned positive photoresist layer comprises:
forming a positive photoresist layer on the material layer;
performing a second exposure process on the positive photoresist layer; and
performing a second develop process to form the patterned positive photoresist layer.

8. The method for forming a patterned material layer of claim 7, wherein the light sources utilized during the second exposure process and the first exposure process are the same.

9. The method for forming a patterned material layer of claim 7, wherein the develop liquids utilized during the second exposure process and the first exposure process are the same.

10. The method for forming a patterned material layer of claim 7, wherein the material layer comprises an organic material layer or an inorganic material layer.

11. The method for forming a patterned material layer of claim 1, wherein the material layer comprises a dielectric layer, a semiconductor layer or a conductor layer.

12. The method for forming a patterned material layer of claim 11, wherein the conductor layer comprises a metal layer or a transparent conductor layer.

13. The method for forming a patterned material layer of claim 12, wherein a material of the transparent conductor layer comprises an indium-tin oxide (ITO), an indium-zinc oxide or a zinc-aluminum oxide.

14. The method for forming a patterned material layer of claim 1, wherein a material of the patterned positive photoresist layer comprises G-line photoresist, I-line photoresist, H-line photoresist or DUV photoresist.
